(19) United States
(12) Patent Application Publication
(10) Pub. No.: US 2024/0295653 A1
(43) Pub. Date: Sep. 5, 2024

(54) REFLECTIVE OPTICAL SENSOR

(71) Applicant: Dexerials Corporation, Tochigi (JP)

(72) Inventors: Akihiro TATEKOUJI, Tochigi (JP); Etsuji OMURA, Tochigi (JP)

(73) Assignee: Dexerials Corporation, Tochigi (JP)

(21) Appl. No.: 18/646,694

(22) Filed: Apr. 25, 2024

Related U.S. Application Data
(63) Continuation of application No. PCT/JP2021/040857, filed on Nov. 5, 2021.

(51) Int. Cl. G01S 17/04; G01S 7/481

(52) U.S. Cl. CPC G01S 17/04; G01S 7/4813

(57) ABSTRACT

A reflective optical sensor (1) has first and second cases (11, 21) each equipped with first and second paraboloid mirrors (14, 24) and the symmetry axes (A1, A2) which intersect on the opposite side to the vertice (V1, V2) with respect to the focal points (F1,F2), and the light emitting element (12) is fitted at or near the focal point (F1) so as to face the first paraboloid mirror (14), the light receiving element (22) is fitted at or near the focal point (F2) so as to face the second paraboloid mirror (24), and the first and second cases (11, 21) are filled with sealing resin (2).

### CROSS-REFERENCE TO RELATED APPLICATION

This application is a continuation of the International PCT application serial no. PCT/JP2021/040857, filed on Nov. 5, 2021. The entirety of the above-mentioned patent application is hereby incorporated by reference herein and made a part of this specification.

### TECHNICAL FIELD

The present disclosure relates to a reflective optical sensor that detects an object by emitting light and detecting the light reflected by the object.

### BACKGROUND ART

Conventionally, reflective optical sensors have been widely used to detect an object by emitting light and detecting the reflected light from a nearby object. A reflective optical sensor is capable of detecting an object in a non-contact manner, and is commonly used in applications such as detecting a rotation angle and detecting the edge of an object.

A reflective optical sensor, for example as in Patent Document #1, has a light emitting element, a light receiving element, and a light blocking wall disposed between them, and the light emitted by the light emitting element is reflected by an object to be detected, and the light receiving element is configured to receive the reflected light. The fact that the output of the light receiving element varies depending on the presence or absence of reflected light and the intensity of the reflected light is utilized for detecting the object.

### PATENT DOCUMENTS

Patent Document #1: Japanese Patent Application Publication No. 2001-308372

In the reflective optical sensor of Patent Document #1, a light emitting element irradiates a nearby detected object with diffused light. Therefore, most of the light emitted by the light emitting element is irradiated onto the object to be detected, but even if the object has a high reflectance, little of the light reflected by the object is incident on the light receiving element. When the ratio of the light incident on the light receiving element to the light emitted by the light emitting element is defined as the coupling efficiency, the results of the ray tracing simulation in the reflective optical sensor of Patent Document #1 show that when the illumination angle of the light emitting element is 90°, the coupling efficiency is approximately 5%, and it is desired to improve the coupling efficiency.

An object of the present disclosure is to provide a reflective optical sensor capable of improving coupling efficiency.

### SUMMARY OF THE DISCLOSURE

The present disclosure presents a reflective optical sensor comprising a light emitting element and a light receiving element, and detecting an object to be detected by reflected light emitted from the light emitting element and reflected by the object to be detected with the light receiving element; wherein provided are a first concave mirror and a second concave mirror each having a parabolic surface including an apex of a parabola formed by rotating the parabola around a symmetry axis of the parabola as a reflecting surface, a first case including the first concave mirror and a second case including the second concave mirror, the first case and the second case are connected such that a first symmetry axis of the first concave mirror and a second symmetry axis of the second concave mirror are coupled so as to intersect each other, on an opposite side to a first vertex of the first concave mirror with respect to a first focal point of the first concave mirror, and on opposite side to a second vertex of the second concave mirror with respect to a second focal point of the second concave mirror, the light emitting element is arranged at or near the first focal point of the first case such that a light emitting surface of the light emitting element facing the first concave mirror is orthogonal to the first symmetry axis, the light receiving element is arranged at or near the second focal point of the second case such that a light receiving surface of the light receiving element facing the second concave mirror is orthogonal to the second symmetry axis, the light emitted by the light emitting element is reflected by the first concave mirror and is irradiated onto the object to be detected, the reflected light reflected by the object to be detected is irradiated onto the second concave mirror, and the light receiving element is configured to detect the reflected light that is reflected by the second concave mirror so as to be condensed toward the second focal point.

According to the above configuration, in the reflective optical sensor, the light emitting element irradiates light toward the first concave mirror at or near the focal point of the first concave mirror, and the light reflected by the first concave mirror is irradiated onto the object to be detected. The light reflected by the object to be detected is irradiated onto a second concave mirror, and the reflected light is condensed by the second concave mirror toward a second focal point and enters the light receiving element. Due to the nature of the paraboloid, the light emitted from the light emitting element is reflected by the first concave mirror and becomes parallel light, so a constant light is irradiated regardless of the distance from the reflective optical sensor, and is reflected by the object to be detected. Most of the reflected light reflected from the flat reflective surface of the object to be detected is irradiated onto the second concave mirror as parallel light, and is reflected and focused by the second concave mirror toward the second focal point. Therefore, most of the light from the light emitting element can be made into parallel light and irradiated onto the object to be detected, and the reflected light can be collected and detected by the light receiving element, so the coupling efficiency can be improved. Here, the coupling efficiency is defined by the ratio of amount of received light at the light receiving element with respect to amount of emitted light at the light emitting element.

In addition, since parallel light is irradiated, the object to be detected can be irradiated with a constant light regardless of the distance from the reflective optical sensor, and a high coupling efficiency can be obtained between the detected object and the reflective optical sensor while keeping wide distance range.

In a first applicable aspect, the light emitting element is housed in the first case, the light receiving element is housed in the second case, and a sealing resin through which light from the light emitting element passes is placed in the first case and the second case.

According to the above configuration, the sealing resin protects the light emitting element, the light receiving element, and the reflecting surfaces of the first and second reflecting mirrors from deterioration and damage, and also prevents the light emitting element and the light receiving element from swinging. Thus, a decrease in coupling efficiency can be prevented.

In a second applicable aspect, the refrective optical senor further comprises a light shielding film that blocks light from the light emitting element between the sealing resin filled in the first case and the sealing resin filled in the second case.

According to the above configuration, the light shielding film can prevent the light from the light emitting element from entering the second concave mirror or the light receiving element without being reflected by the object to be detected, thereby preventing false detection of the object by stray light.

In a third applicable aspect, the first case and the second case are coupled with a light blocking member interposed therebetween that blocks light from the light emitting element. According to the above configuration, the light shielding member can prevent the light from the light emitting element from entering the second concave mirror or the light receiving element, without being deflected by the object to be detected, thereby preventing erroneous detection of the object to be detected due to stray light. Further, by adjusting the thickness and shape of the light shielding member, reflective optical sensors with different detection positions can be easily formed.

According to the reflective optical sensor of the present disclosure, coupling efficiency can be improved.

### BRIEF DESCRIPTION OF THE DRAWINGS

FIG. 1 is a plan view of a reflective optical sensor according to an embodiment of the present disclosure;

FIG. 2 is a sectional view taken along the line II-II in FIG. 1;

FIG. 3 is an explanatory diagram of a parabola;

FIG. 4 is an explanatory diagram of assembling a reflective optical sensor;

FIG. 5 is an explanatory diagram of the assembly of the light emitting unit;

FIG. 6 is an explanatory diagram of forming a joint surface of a light emitting unit;

FIG. 7 is an example of a ray tracing simulation in the reflective optical sensor according to the embodiment;

FIG. 8 is a diagram showing the relationship between distance h and coupling efficiency of the reflective optical sensor according to the embodiment;

FIG. 9 is a diagram showing coupling efficiency in contour lines when distance h and angle θ are used as parameters;

FIG. 10 is a contour diagram showing coupling efficiency when the focal lengths of the first and second concave mirrors and distance h are used as parameters;

FIG. 11 is a contour diagram showing coupling efficiency when the distance between the vertices of the first and second concave mirrors and distance h are used as parameters;

FIG. 12 is a plan view of a reflective optical sensor including a light shielding member; and

FIG. 13 is a sectional view taken along the line XIII-XIII in FIG. 12.

### DESCRIPTION OF EMBODIMENTS

Hereinafter, the form for implementing the present disclosure is demonstrated based on Embodiments.

### Embodiment

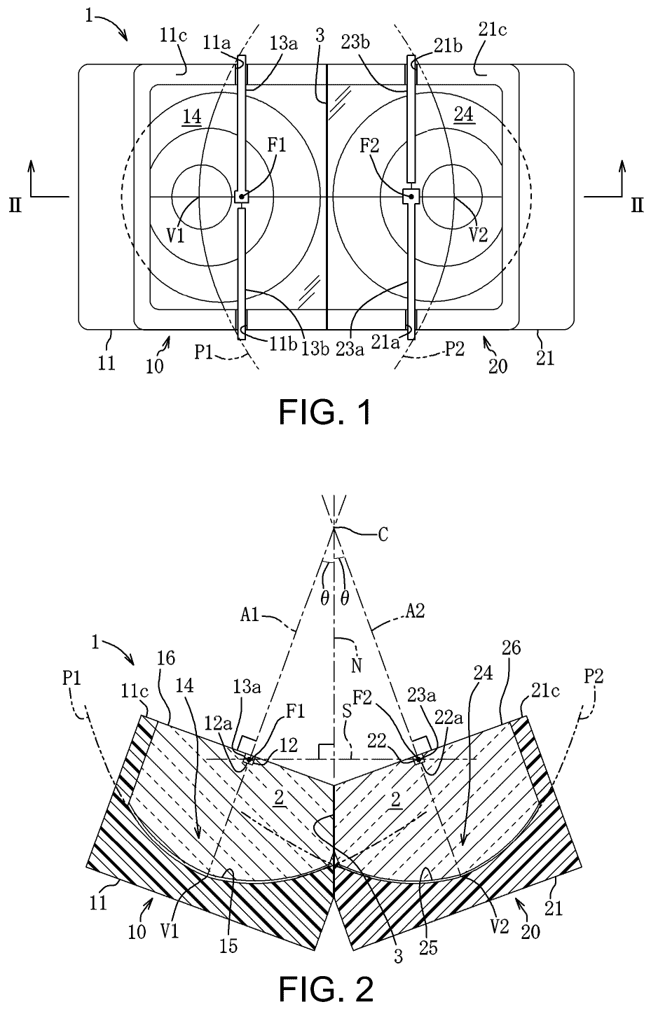

As shown in FIGS. 1 and 2, the reflective optical sensor 1 is formed by combining a light emitting unit 10 that emits light and a light receiving unit 20 that receives light and outputs a photocurrent. The light emitting unit 10 includes a first case 11 with an open top surface, a light emitting element 12, and a pair of first lead frames 13a and 13b. The light receiving unit 20 includes a second case 21 with an open top surface, a light receiving element 22, and a pair of second lead frames 23a and 23b. Although the open side of the combined first and second cases 11 and 21 will be described as upper direction in reflective optical sensor 1, the reflective optical sensor 1 can be used in various postures depending on the application.

The first case 11 is formed into a box shape without a top surface and a part of the side wall on the side of the light receiving unit 20 is missing, and a first concave mirror 14 is formed at the bottom with its reflective surface facing the open top surface of the first case 11. The second case 21 is formed into a box shape without a top surface and a part of the side wall on the side of the light emitting unit 10 is missing, and a second concave mirror 24 is formed at the bottom with its reflective surface facing the open top surface of the case 21.

The first concave mirror 14 is a paraboloid formed by rotating the first parabola P1 around the first symmetry axis A1 of the first parabola P1, and a reflective surface including a first vertex V1 of the first parabola P1 is formed. A reflective film 15 containing a metal such as gold or titanium is formed on this paraboloid. The second concave mirror 24 is a paraboloid formed by rotating the second parabola P2 around the second symmetry axis A2, and a reflective surface including a second vertex V2 of the second palabola P2 is formed. A reflective film 25 containing a metal such as gold or titanium is formed on this paraboloid.

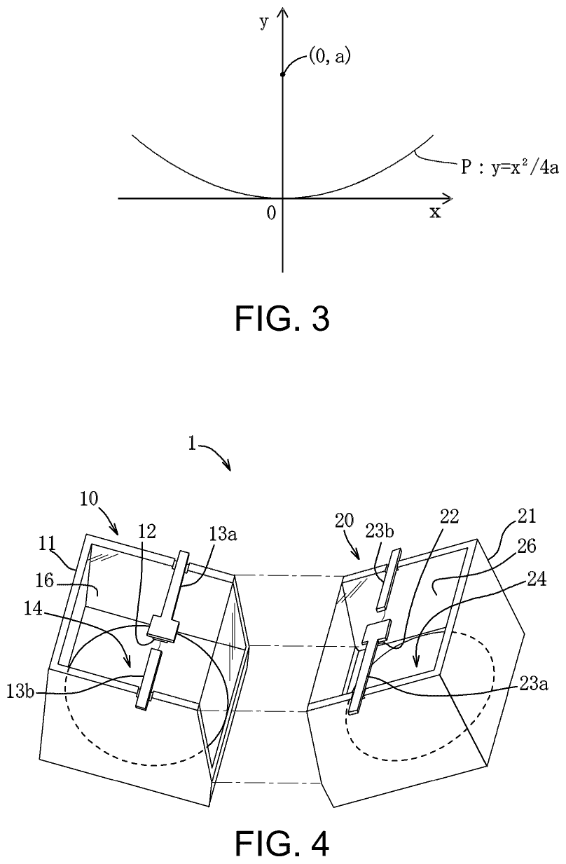

In the parabola P expressed by y=x²/(4a) on the xy plane as shown in FIG. 3, the first and second parabolas P1 and P2 are those with a=4 mm, for example. Note that the y-axis is the symmetry axis of the parabola P, the position of the origin is the vertex of the parabola P, and the position of (x, y)=(0, a) is the focal point of the parabola P. The value of a may be different between the first parabola P1 and the second parabola P2, but it is preferable to make the first case 11 and the second case 21 to be the same shape and size by setting the same value of a. This is advantageous from the viewpoint of fabrication cost, etc.

As shown in FIGS. 1 and 2, the focus of the first parabola P1 forming the first concave mirror 14 is the first focus F1. Further, the focal point of the second parabola P2 forming the second concave mirror 24 is the second focal point F2. The first symmetry axis A1 and the second symmetry axis A2 intersect with respect to the first focal point F1 on the opposite side to the first vertex V1 and with respect to the second focal point F2 on the opposite side to the second vertex V2. The point where the first symmetry axis A1 and the second symmetry axis A2 intersect is defined as an intersection C. A plane that is perpendicular to a straight line N that passes through the intersection C and intersects the first symmetry axis A1 and the second symmetry axis A2 at an angle θ is defined as the reference plane S including the first focal point F1 and the second focal point F2 in the reflective optical sensor 1.

The joint surface between the light emitting unit 10 and the light receiving unit 20 is a plane included in a plane that includes the straight line N and is perpendicular to the reference plane S, and is inclined at an angle θ with respect to the first symmetry axis A1 and the second symmetry axis A2 respectively.

In the light emitting unit 10, the proximal end portion of the first lead frame 13a, on which the light emitting element 12 is mounted at the distal end, is fixed to the recess 11a of the first case 11, and the light emitting element 12 is located at or near the first focal point F1. The other first lead frame 13b has its proximal end portion fixed to the recess 11b of the first case 11 so that its distal end does not come into contact with the first lead frame 13a. The light emitting element 12 and the first lead frames 13a, 13b are connected by a conductive wire such as a gold wire, for example, so that power for light emission is supplied to the light emitting element 12 via the first lead frames 13a, 13b.

The recesses 11a and 11b are formed by recessing a portion of the open end of the first case 11 corresponding to the first focal point F1 from the open end surface 11c toward the bottom in order to position the first lead frames 13a and 13b. When the first lead frame 13a is fixed to the recess 11a so that the light emitting element 12 faces the first concave mirror 14, the light emitting element 12 is fixed so that the light emitting surface 12a of the light emitting element 12 is perpendicular to the first symmetry axis A1 and this light emitting element 12 is housed in the first case 11.

In addition, in the light receiving unit 20, the proximal end portion of the second lead frame 23a to which the light receiving element 22 is fixed at the distal end thereof is fixed to the recess 21a of the second case 21. A light receiving element 22 is arranged at or near the second focal point F2. The other second lead frame 23b has its proximal end portion fixed in the recess 21b of the second case 21 so that its distal end does not come into contact with the second lead frame 23a. The light receiving element 22 and the second lead frames 23a, 23b are electrically connected by a conductive wire such as a gold wire so that a photocurrent is output from the light receiving element 22 via the second lead frames 23a, 23b.

The recesses 21a and 21b are formed by recessing a portion of the open end of the second case 21 corresponding to the second focal point F2 from the open end surface 21c toward the bottom in order to position the second lead frames 23a and 23b. When the second lead frame 23a is fixed to the recess 21a so that the light receiving element 22 faces the second concave mirror 24, the light receiving element 22 is fixed so that the light receiving surface 22a of the light receiving element 22 is perpendicular to the second symmetry axis A2, the light receiving element 22 is housed in the second case 21.

The inside of the first case 11 housing the light emitting element 12 and the inside of the second case 21 housing the light receiving element 22 are filled with sealing resin 2, respectively. The light emitting element 12, the light receiving element 22, the first and second cocave mirrors 14 and 24 are covered with sealing resin 2. The first lead frames 13a, 13b and the second lead frames 23a, 24b may also be covered with the sealing resin 2.

Assuming that the surface of the sealing resin 2 exposed on the top surface of the first case 11 is the light emitting side surface 16, the light emitting side surface 16 is formed flat and orthogonal to the first symmetry axis A1 so that the difference in level from the open side end surface 11c of the first case 11 is small. Furthermore, if the surface of the sealing resin 2 exposed on the upper surface of the second case 21 is defined as the light receiving side surface 26, the light receiving side surface 26 is formed flat and perpendicular to the second symmetry axis A2 so that the difference in level from the open side end surface 21c of the second case 21 is small.

The sealing resin 2 is an epoxy based synthetic resin that has a translucent property that allows the light from the light emitting element 12 to pass therethrough, and that allows visible light or infrared light to pass through. The sealing resin 2 protects the light emitting element 12, the light receiving element 22, and the reflective films 15 and 25 of the first and second concave mirrors 14 and 24 from deterioration and damage, respectively.

As shown in FIGS. 2 and 4, the reflective optical sensor 1 is arranged such that the first symmetry axis A1 of the first concave mirror 14 and the second symmetry axis A2 of the second concave mirror 24 intersect at a predetermined intersection angle 2θ, by combining the light emitting unit 10 and the light receiving unit 20. The formation of these light emitting unit 10 and light receiving unit 20 will be explained.

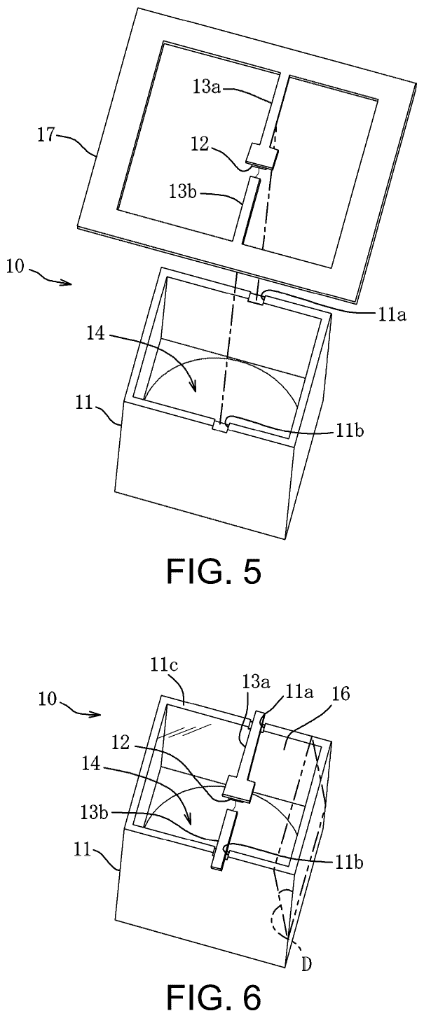

As shown in FIG. 5, first lead frames 13a and 13b are integrally formed in the frame 17. The light emitting element 12 is mounted on the tip of the first lead frame 13a, and the light emitting element 12 and the first lead frames 13a, 13b are electrically connected by conductive wires. The proximal ends of the first lead frames 13a, 13b of this frame 17 are placed in alignment with the recesses 11a, 11b of the rectangular box shaped first case 11 with an open top surface, and are fixed in the recesses 11a, 11b using adhesive, for example.

Next, as shown in FIG. 6, the first case 11 is filled with the sealing resin 2 so that the light emitting side surface 16 of the sealing resin 2 is formed flat and has no level difference with respect to the open side end surface 11c of the first case 11. After the sealing resin 2 is cured, the base end portions of the first lead frames 13a, 13b are cut from the frame 17, and the frame 17 is removed. Next, a part of the first case 11 and a part of the sealing resin 2 on the light receiving unit 20 side are removed by grinding or cutting along a plane D that approaches the first symmetry axis A1 as the open side of the first case 11 approaches. Then, the light emitting unit 10 having a coupling surface for coupling with the light receiving unit 20 is formed. As shown in FIG. 2, the plane containing this bonding surface (plane D) intersects the first symmetry axis A1 at an angle θ.

Although not shown, in the light receiving unit 20, similarly to the light emitting unit 10, the frame in which the second lead frames 23a and 23b, which are electrically connected to the light receiving element 22, are integrally formed is fixed to the recesses 21a and 21b of second case 21. In this state, the sealing resin 2 is filled in the second case 21. After the frame is removed, a bonding surface for coupling with the light emitting unit 10 is formed, and a plane including this bonding surface intersects the second symmetry axis A2 at an angle θ.

The light shielding film 3 is formed on either or both of the bonding surface of the light emitting unit 10 and the bonding surface of the light receiving unit 20, and the bonding surfaces of the light emitting unit 10 and the light receiving unit 20 are bonded together using adhesive, for example, thereby the reflective optical sensor 1 is formed (see FIG. 4). The light shielding film 3 is a film that blocks light from the light emitting element 12 and contains a metal such as gold or titanium. In FIGS. 1 and 2, a light shielding film 3 is formed on the coupling surface formed on the light receiving unit 20.

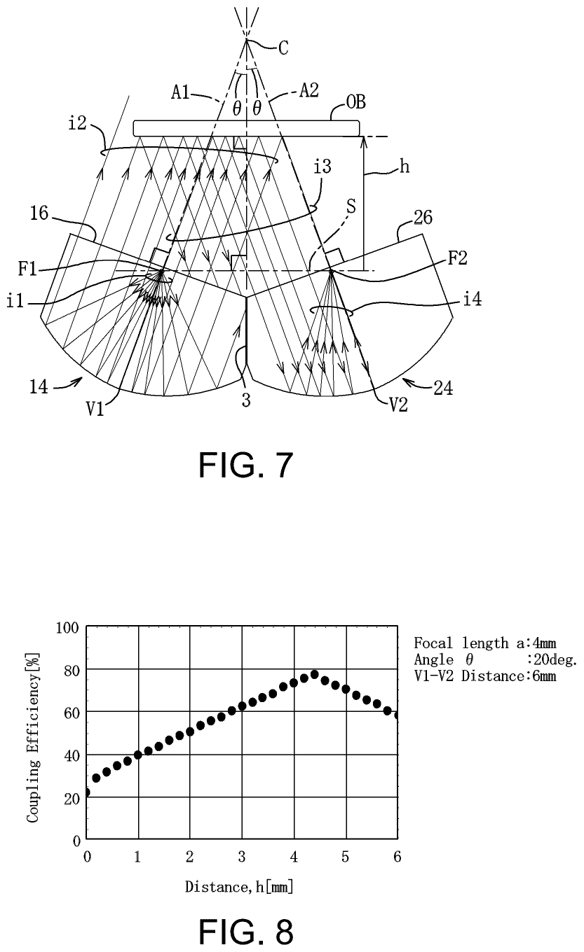

Detection of the object to be detected OB by the reflective optical sensor 1 will be explained. As shown in FIG. 7, the light i1 emitted from the light emitting element 12 at or near the first focal point F1 is reflected by the first concave mirror 14, and most of it is reflected and is irradiated to the object OB as light i2 parallel to the first symmetry axis A1 due to the nature of the paraboloid. Since the light emitting surface 16 of the light emitting unit 10 is orthogonal to the first symmetry axis A1, the light i2 emitted from the light emitting unit 10 is not refracted and travels straight when it is emitted into the air from the light emitting surface 16. The light shielding film 3 prevents the light emitted from the light emitting element 12 from entering the second concave mirror 24 or the light receiving element 22 without reflecting by the object OB, thereby preventing false detection of the object to be detected OB due to stray light, for example. Note that the light emitting element 12 is a light emitting diode with an irradiation angle of 90°, for example.

When the object OB having a flat reflecting surface parallel to the reference plane S and having a high reflectance is at the detection position, part or all of the light i2 is reflected by the object OB as the reflected light i3. Part or all of the light i3 is irradiated onto the second concave mirror 24 as parallel light parallel to the second symmetry axis A2. The amount of light irradiated to the second concave mirror 24 varies depending on the size and position of the object OB. Since the light receiving surface 26 of the light receiving unit 20 is orthogonal to the second symmetry axis A2, when a part or all of the reflected light i3 enters the light receiving surface 26 from the air, it is not refracted and travels straight to the second concave mirror 24.

Of the reflected light i3, all of the light irradiated onto the second concave mirror 24 is reflected and condensed by the second concave mirror 24 toward the second focal point F2, like the reflected light i4, due to the nature of the paraboloid. Then, the reflected light i4 enters the light receiving element 22 at or near the second focal point F2, a photocurrent is generated in the light receiving element 22, and the photocurrent is outputted via the second lead frames 23a and 23b. On the other hand, when the object to be detected OB is not at the detection position, the light i2, which is a part of the light from the light emitting element 11, exits to the outside and is not irradiated to the second concave mirror 24, and does not enter the light receiving element 22. Therefore, in the reflective optical sensor 1, the light from the light emitting element 12 is reflected by the object to be detected OB, the reflected light i3 is reflected by the second concave mirror 24, and this reflected light i4 is detected by the light receiving element 22, thereby object OB can be detected.

When coupling efficiency is defined as the proportion of light incident on the light receiving element 22 out of the light emitted by the light emitting element 12, the higher the coupling efficiency, the greater the photocurrent output of the reflective photosensor 1. Therefore, it is possible to easily prevent false detection of the object to be detected OB due to the stray light, for example, and it is also possible to reduce power consumption by reducing the light intensity of the light emitting element 12, so it is desirable to achieve high coupling efficiency.

Here, based on the ray tracing simulation shown in FIG. 7, the distance h from the reference surface S of the reflective optical sensor 1 to the object OB is used as a parameter, FIG. 8 shows the coupling efficiency when the object OB is separated from the reference surface S. The half angle θ of the intersection angle 2θ of the first and second symmetry axes A1 and A2 is 20°, and the distance between the first vertex V1 and the second vertex V2 is 6 mm. The first and second concave mirrors 14 and 24 have a focal length of 4 mm and are formed symmetrically with respect to a straight line N that passes through the intersection C of the first and second symmetry axes A1 and A2 and is orthogonal to the reference plane S. It is assumed that the object OB has a reflecting surface large enough to reflect most of the irradiated light, and contact with the reflective optical sensor 1 is not considered.

As the distance h from the reference surface S to the object OB increases, the coupling efficiency increases until the distance h=4.4 mm, and as the distance h further increases, the coupling efficiency decreases. The coupling efficiency is about 20% when the distance h=0 mm, and higher coupling efficiency can be obtained up to at least the distance h=6 mm. Therefore, the detection position range where a higher coupling efficiency can be obtained than the conventional one (coupling efficiency of 5%) is in the range h=0 to 6 mm.

Therefore, in order to prevent damage to the reflective optical sensor 1 due to contact between the reflective optical sensor 1 and the object OB, high coupling efficiency can be obtained even if a certain distance h is secured. Furthermore, if the object to be detected OB is smaller than the irradiation range of the irradiated parallel light, the reflected light i3 will decrease, but since the coupling efficiency is high, the small object OB can be detected. Note that since the coupling efficiency changes linearly with the distance h, it is estimated that the coupling efficiency is 20% or more up to at least the distance h=8 mm.

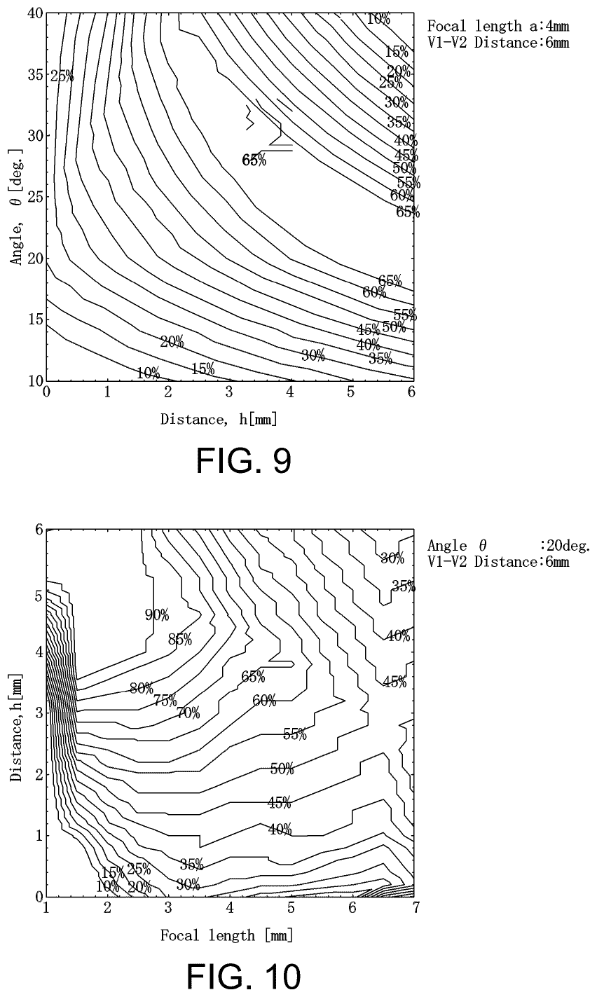

The coupling efficiency when distance h and angle θ are used as parameters is shown in contour lines in FIG. 9. The distance between the first vertex V1 and the second vertex V2 is 6 mm, and the focal length of the first and second concave mirrors 14 and 24 is 4 mm. As the angle θ increases, the intersection C of the first and second symmetry axes A1 and A2 approaches the reflective optical sensor 1, and therefore the range of distance h in which high coupling efficiency can be obtained approaches the reference plane S. Referring to FIG. 9, it is possible to form a reflective optical sensor 1 in which the angle θ is set so as to obtain high coupling efficiency in accordance with the detection position of the object OB. Further, referring to FIG. 9, the detection position by the reflective optical sensor 1 can be set at a distance h where high coupling efficiency can be obtained.

The focal lengths of the first and second concave mirrors 14 and 24 and the coupling efficiency when the distance h is used as parameters are shown in contour lines in FIG. 10. The distance between the first vertex V1 and the second vertex V2 is 6 mm, and the angle θ is 20°. As the focal length becomes smaller and the distance h becomes larger, the coupling efficiency improves. As the focal length becomes smaller, the irradiation range of the light irradiated onto the object OB becomes smaller, so it becomes easier for the reflected light i3 to enter the second concave mirror 24, and high coupling efficiency can be obtained. Referring to FIG. 10, a reflective optical sensor 1 can be formed in which the focal lengths of the first and second concave mirrors 14 and 24 are set so as to obtain high coupling efficiency in accordance with the detection position of the object OB. Further, referring to FIG. 10, the detection position by reflective optical sensor 1 can be set at a distance h where high coupling efficiency can be obtained.

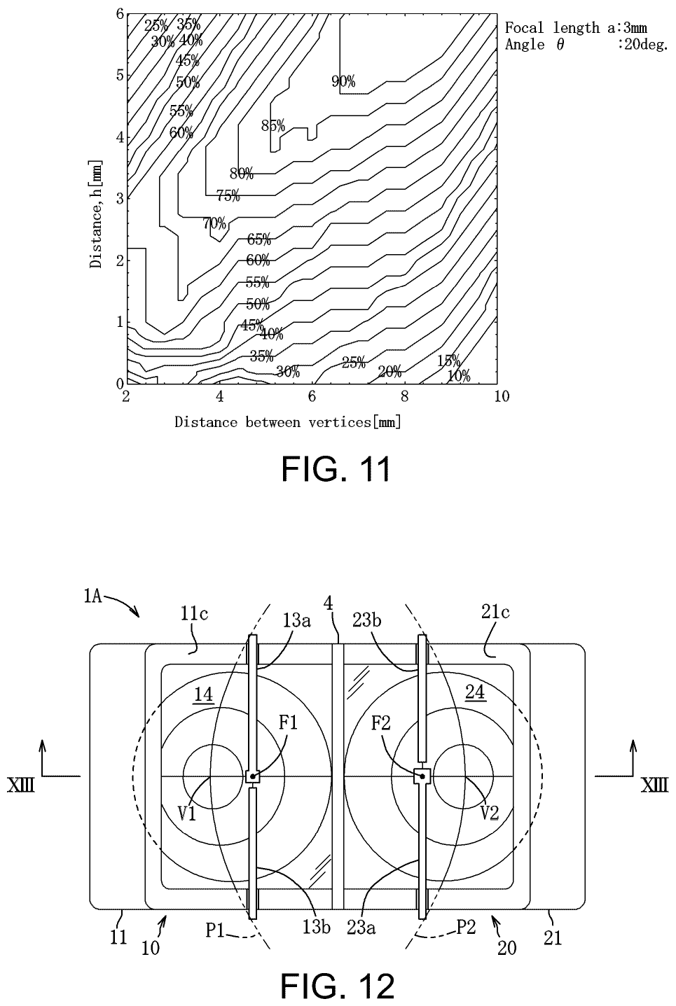

The distance between the first vertex V1 and the second vertex V2 and the coupling efficiency when the distance h is used as a parameter are shown in contour lines in FIG. 11. The focal length of the first and second concave mirrors 14 and 24 is 3 mm, and the angle θ is 20°. As the distance between the first vertex V1 and the second vertex V2 increases, the intersection C of the first and second symmetry axes A1 and A2 becomes farther away from the reference plane S. Referring to FIG. 11, a reflective optical sensor 1 can be formed in which the distance between the first vertex V1 and the second vertex V2 is set so as to obtain high coupling efficiency according to the detection position of the object OB. Further, referring to FIG. 11, the detection position by reflective optical sensor 1 can be set at a distance h where high coupling efficiency can be obtained.

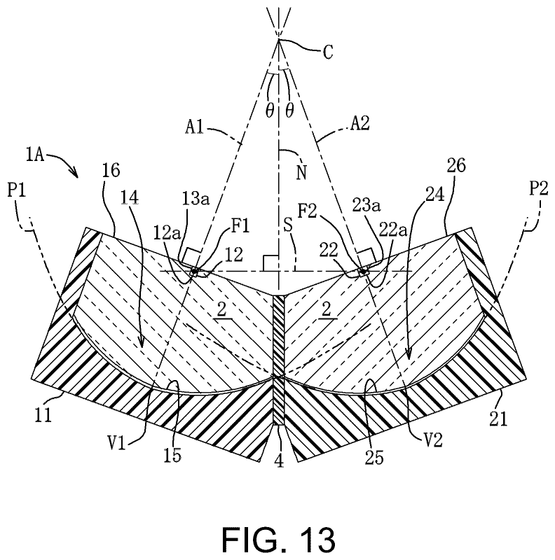

As shown in FIGS. 12 and 13, it is also possible to form a reflective optical sensor 1A in which a light shielding member 4 is sandwiched between a light emitting unit 10 and a light receiving unit 20 and coupled together instead of the light-shielding film 3. In this case, the distance between the first vertex V1 and the second vertex V2 can be adjusted depending on the thickness of the light shielding member 4. Furthermore, by making the cross sectional shape of the light shielding member 4 trapezoidal, for example, the intersection angle 2θ between the first symmetry axis A1 and the second symmetry axis A2 can be adjusted, and joint surfaces formed on the light emitting unit 10 and the light receiving unit 20 can be omitted. Therefore, by changing the thickness and shape of the light shielding member 4, reflective optical sensors 1A with different detection positions can be easily formed.

The functions and effects of the reflective optical sensors 1 and 1A described above will be explained. In the reflective optical sensors 1 and 1A, the light emitting element 12 irradiates light i1 toward the first concave mirror 14 from the position at or near the first focal point F1 of the first concave mirror 14, and the light i2 reflected by the first concave mirror 14 is irradiated onto the object OB. Then, the reflected light i3 reflected by the object to be detected OB is irradiated onto the second concave mirror 24, and the reflected light i4 reflected by the second concave mirror 24 to be condensed toward the second focal point F2 so as to be received by the light receiving element 22.

Due to the nature of the paraboloid, the light i1 emitted from the light emitting element 12 is reflected by the first concave mirror 14 and becomes parallel light, so the light i2 remains constant regardless of the distance from the reflective optical sensor 1, 1A. A part of the reflected light i3 reflected by the flat reflective surface of the object OB is irradiated onto the second concave mirror 24 as parallel light, and is reflected and focused by the second concave mirror 24 toward the second focal point F2. Therefore, most of the diffused light emitted from the light emitting element 12 is converted into parallel light and irradiated onto the object OB, and the reflected light i3 reflected by the object OB is collected and detected by the light receiving element 22. Therefore, when the ratio of light incident on the light receiving element 22 to the light emitted by the light emitting element 12 is defined as the coupling efficiency, the coupling efficiency can be improved. In addition, since parallel light is irradiated, a constant light can be irradiated to the object OB regardless of the distance from the reflective optical sensor 1, 1A, and while having high coupling efficiency, the distance range between the optical sensors 1 and 1A and the object OB can be widened.

The light emitting element 12 is housed in the first case 11, the light receiving element 22 is housed in the second case 21, and the sealing resin 2 through which the light from the light emitting element 12 passes is filled inside the first case 11 and the second case 21. Therefore, the sealing resin 2 protects the light emitting element 12, the light receiving element 22, and the reflecting surfaces of the first and second concave mirrors 14 and 24 from deterioration and damage, and also prevents the light emitting element 12 and the light receiving element 22 from swinging. This can prevent a decrease in coupling efficiency.

The light shielding film 3 between the sealing resin 2 filled in the first case 11 and the sealing resin 2 filled in the second case 21 prevents the light of the light emitting element 12 from entering the concave mirror 24 or the light receiving element 22 without reflecting by the object OB, it is possible to prevent false detection of the object OB due to stray light.

When the first case 11 and the second case 21 are combined with the light shielding member 4, the light from the light emitting element 12 is prevented from entering the second concave mirror 24 or the light receiving element 22 without reflecting by the object OB, it is possible to prevent false detection of the object OB due to stray light. Furthermore, by adjusting the thickness and shape of the light shielding member 4, reflective optical sensors 1A with different detection positions can be easily made.

Although not shown, instead of the first lead frames 13a and 13b, the light emitting element 12 is fixed to a cover member that is transparent to the light from the light emitting element 12, and the light emitting element 12 is electrically connected to this cover member. This lid member may be fixed to the open side of the first case 11 by forming a plurality of wiring lines. Furthermore, instead of the second lead frames 23a and 23b, the light receiving element 22 is fixed to a lid member that is transparent to the light from the light emitting element 12, and a plurality of wirings electrically connected to the light receiving element 22 are connected to this lid member. The lid member may be fixed to the open side of the second case 21 by forming a lid member. In this case, since the light emitting element 12 and the light receiving element 22 do not swing, filling with the sealing resin 2 can be omitted. If filling with the sealing resin 2 is omitted, the first and second cases 11 and 21 are combined with interposing the light shielding member 4 therebetween.

In addition, those skilled in the art can implement various modifications to the embodiments described above without departing from the spirit of the present disclosure.

1. A reflective optical sensor comprising a light emitting element and a light receiving element, and detecting an object to be detected by reflected light emitted from the light emitting element and reflected by the object to be detected with the light receiving element; wherein
provided are a first concave mirror and a second concave mirror each having a parabolic surface including an apex of a parabola formed by rotating the parabola around a symmetry axis of the parabola as a reflecting surface, a first case including the first concave mirror and a second case including the second concave mirror,
the first case and the second case are connected such that a first symmetry axis of the first concave mirror and a second symmetry axis of the second concave mirror are coupled so as to intersect each other, on an opposite side to a first vertex of the first concave mirror with respect to a first focal point of the first concave mirror, and on opposite side to a second vertex of the second concave mirror with respect to a second focal point of the second concave mirror,
the light emitting element is arranged at or near the first focal point of the first case such that a light emitting surface of the light emitting element facing the first concave mirror is orthogonal to the first symmetry axis,
the light receiving element is arranged at or near the second focal point of the second case such that a light receiving surface of the light receiving element facing the second concave mirror is orthogonal to the second symmetry axis,
the light emitted by the light emitting element is reflected by the first concave mirror and is irradiated onto the object to be detected,
the reflected light reflected by the object to be detected is irradiated onto the second concave mirror, and
the light receiving element is configured to detect the reflected light that is reflected by the second concave mirror so as to be condensed toward the second focal point.

2. The reflective optical sensor according to claim 1, wherein the light emitting element is housed in the first case, the light receiving element is housed in the second case, and a sealing resin through which light from the light emitting element passes is placed in the first case and the second case.

3. The reflective optical sensor according to claim 2, wherein further comprises a light shielding film that blocks light from the light emitting element between the sealing resin filled in the first case and the sealing resin filled in the second case.

4. The reflective optical sensor according to claim 1, wherein the first case and the second case are coupled with a light blocking member interposed therebetween that blocks light from the light emitting element.

5. The reflective optical sensor according to claim 2, wherein the first case and the second case are coupled with a light blocking member interposed therebetween that blocks light from the light emitting element.
